(19) United States
(12) Patent Application Publication
(10) Pub. No.: US 2006/0038184 A1
(43) Pub. Date: Feb. 23, 2006

(54) Light-emitting device, manufacturing method of particle and manufacturing method of light-emitting device

(76) Inventor: Hironobu Sai, Kyoto-shi (JP)

Correspondence Address: MCDERMOTT WILL & EMERY LLP, 600 13TH STREET, N.W., WASHINGTON, DC, 20005-3096, US

(21) Appl. No.: 11/202,367

(22) Filed: Aug. 12, 2005

(30) Foreign Application Priority Data
Aug. 12, 2004 (JP) P2004-235536

(51) Int. Cl. H01L 33/00

(52) U.S. Cl. 257/79; 257/103; 257/95; 257/94; 257/87

(57) ABSTRACT

A light-emitting device includes, in order of mention: a positive hole supply layer; a particle layer comprising particles of semiconductor crystals and a conductive medium, the conductive medium which fills spaces between the particles and confines positive holes and electrons in the particles by dint of an energy gap larger than those of the particles; and an electron supply layer. Positive holes, which are supplied from the positive hole supply layer through the conductive medium to the particles, and electrons, which are supplied from the electron supply layer through the conductive medium to the particles, are caused to recombine to emit light in the particles.

### CROSS REFERENCE TO RELATED APPLICATION

This application is based upon and claims the benefit of priority from the prior Japanese Patent Application No. P2004-235536, filed on Aug. 12, 2004; the entire contents of which are incorporated herein by reference.

### BACKGROUND OF THE INVENTION

1. Field of the Invention

The present invention relates to a light-emitting device in which light is emitted from particles of semiconductor crystals, a method of manufacturing the particles of semiconductor crystals which are provided in the light-emitting device, and a method of manufacturing the light-emitting device.

2. Description of the Related Art

In a known light-emitting device, a p-type semiconductor layer which supplies positive holes, a light-emitting layer which causes positive holes and electrons to recombine to emit light, and an n-type semiconductor layer which supplies electrons are stacked in this order. A double-heterostructure is generally adopted in which the light-emitting layer has an energy gap smaller than those of the p-type and n-type semiconductor layers and in which positive holes and electrons are confined by the differences between the energy gaps.

The wavelength of light emitted by recombination radiation is determined by an energy gap for the recombination of a positive hole and an electron. Heretofore, semiconductor layers have been deposited, and energy gaps have been formed according to the material compositions of the respective layers. Accordingly, energy gaps capable of being formed have been limited by the lattice constant of a substrate. Thus, it has been possible to select the wavelength of light emitted from a light-emitting device only among energy gaps capable of being formed according to material compositions which matches the lattice constant of the substrate. In particular, it has been difficult to emit light of energies higher than the characteristic values of the material compositions.

On the other hand, a method has been also proposed in which the wavelength of light emitted from a light-emitting device is controlled according to not material composition but the structure. Provided is a structure in which a thin insulating film surrounds such microcrystals that a quantum effect manifests, which microcrystals are made of a group IV semiconductor and have a size of not more than 10 nm. The emission wavelength can be controlled according to the sizes of the microcrystals: e.g., infrared to red in the case where the sizes of the microcrystals, i.e., the diameters of the particles, are 5 nm; and red in the case of 3 nm.

However, the microcrystals which confine positive holes and electrons are made of a group IV semiconductor and surrounded by an insulator. Accordingly, if positive holes and electrons pass through the insulator by the tunneling effect and are not confined in the group IV semiconductor, it has been impossible to cause recombination radiation.

Further, since the microcrystals are formed on a semiconductor by dint of crystal growth, some parts of the microcrystals are in contact with a layer on which they are deposited. Accordingly, the effect of confining positive holes and electrons in the microcrystals has been weaker. Furthermore, it has been difficult to form structure's having sizes of not more than 10 nm with high yield.

### BRIEF SUMMARY OF THE INVENTION

The present invention has been made considering the problems, and its object is to provide a light-emitting device which emits light of an arbitrary wavelength, a method of manufacturing particles of semiconductor crystals which are provided in the light-emitting device, and a method of manufacturing the light-emitting device.

A first aspect of the present invention is summarized as a light-emitting device including, in order of mention: a positive hole supply layer; a particle layer including particles of semiconductor crystals and a conductive medium, the conductive medium which fills spaces between the particles and confines positive holes and electrons in the particles by dint of an energy gap larger than those of the particles; and an electron supply layer, wherein positive holes, which are supplied from the positive hole supply layer through the conductive medium to the particles, and electrons, which are supplied from the electron supply layer through the conductive medium to the particles, are caused to recombine to emit light in the particles.

A second aspect of the present invention is summarized as a light-emitting device including, in order of mention: a p-type semiconductor layer; a particle layer including particles of semiconductor crystals and a conductive medium, the conductive medium which fills spaces between the particles and confines positive holes and electrons in the particles by dint of an energy gap larger than those of the particles; and an n-type semiconductor layer, wherein positive holes, which are supplied from the p-type semiconductor layer through the conductive medium to the particles, and electrons, which are supplied from the n-type semiconductor layer through the conductive medium to the particles, are caused to recombine to emit light in the particles.

In the first or second aspect of the present invention, sizes of the particles may be not more than the de Broglie wavelengths of an electron and a positive hole. In the first or second aspect of the present invention, the particles may have sizes with which a quantum confinement effect manifests. In the first or second aspect of the present invention, sizes of the particles may be not less than 0.5 nm nor more than 100 nm. In the first or second aspect of the present invention, the particles may have quantum well structures.

In the first or second aspect of the present invention, a carrier density of the conductive medium may be not less than 10¹⁴ nor more than 10¹⁷ (cm⁻³). In the first or second aspect of the present invention, the particle layer may include particles which are different in at least one of size and/or material composition. In the first or second aspect of the present invention, the particle layer may include a plurality of layers, and the plurality of layers comprise respective particles which are different in at least one of size and/or material composition. In the first or second aspect of the present invention, lights emitted in the particles which are different in at least one of size and/or material composition may be mixed into white light by virtue of additive color mixture. In the first or second aspect of the present invention, the particles may be made of any one of GaAs/InGaAs, AlAs/InGaAs, and InP/InGaAs. In the first or second aspect of the present invention, the conductive medium may be made of a conductive polymer.

A third aspect of the present invention is summarized as a method of manufacturing particles, including the steps of: forming any one of a resist film and a metal oxide film on a semiconductor layer; forming a thin semiconductor film having a thickness approximately equal to sizes of particles to be formed, on any one of the resist film and the metal oxide film; removing any one of the resist film and the metal oxide film to lift off the thin semiconductor film; and crushing the lifted-off thin semiconductor film.

In the third aspect of the present invention, in the step of forming the metal oxide film, AlAs deposited may be oxidized in high-temperature water vapor to form Al₂O₃. In the third aspect of the present invention, in the step of crushing the lifted-off thin semiconductor film, the thin semiconductor film may be crushed by use of ultrasonic waves.

A fourth aspect of the present invention is summarized as a method of manufacturing a light-emitting device, including: adding particles of semiconductor crystals to a conductive medium having an energy gap larger than those of the particles; interposing the conductive medium having the particles added thereto in the step of adding particles, between a p-type semiconductor and an n-type semiconductor; and baking the conductive medium interposed in the step of interposing, while applying pressure to the conductive medium from both of the p-type and n-type semiconductors.

In the fourth aspect of the present invention, in the step of adding particles, the particles of semiconductor crystals maybe added to the conductive polymer liquefied. In the fourth aspect of the present invention, in the step of interposing, the conductive medium may be applied to a surface of any one of the p-type and n-type semiconductor layers by means of spin coating.

### BRIEF DESCRIPTION OF THE SEVERAL VIEWS OF THE DRAWINGS

FIG. 1 is a view for explaining a particle manufacturing process according to one embodiment of the present invention.

FIG. 2 is a view for explaining the particle manufacturing process according to one embodiment of the present invention.

FIG. 3 is a view illustrating one example of a method of crushing a metal oxide film by use of ultrasonic waves, according to one embodiment of the present invention.

FIG. 4 is a view for explaining a light-emitting device manufacturing process according to one embodiment of the present invention.

FIG. 5 is a view for explaining a light-emitting device manufacturing process according to one embodiment of the present invention.

FIG. 6 is a cross-sectional view of another light-emitting device according to one embodiment of the present invention.

FIG. 7 is a cross-sectional view of another light-emitting device of one embodiment of the present invention.

FIG. 8 is a cross-sectional view of another light-emitting device of one embodiment of the present invention.

FIG. 9 is a view for explaining the energy gaps of a conductive medium and a particle which are provided in one embodiment of the present invention.

FIG. 10 is a cross-sectional view of another light-emitting device according to one embodiment of the present invention.

FIG. 11 is a view illustrating a particle having a multiple quantum well structure according to one embodiment of the present invention.

### DETAILED DESCRIPTION OF THE INVENTION

Hereinafter, embodiments of the present invention will be described in detail with reference to the drawings. Note that the present invention is not limited to embodiments described below.

### FIRST EMBODIMENT

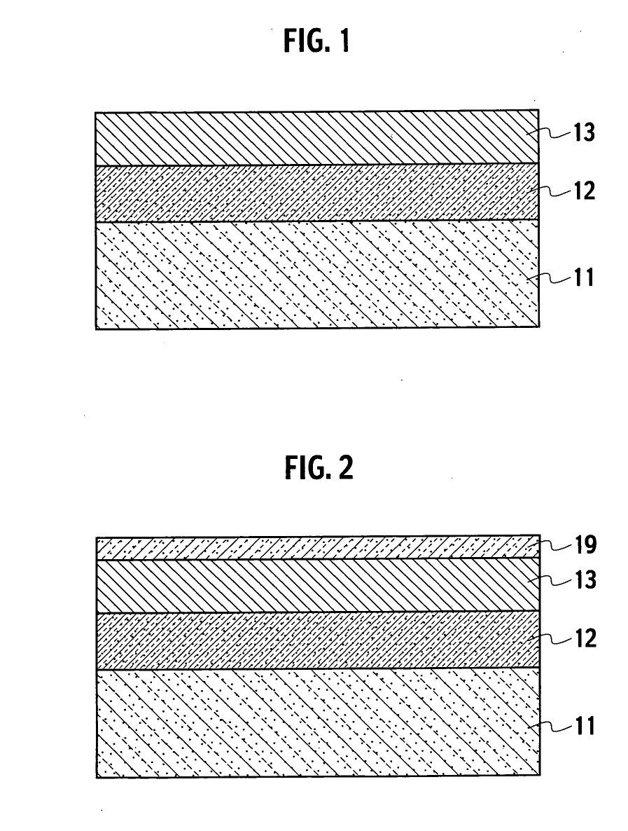

A particle manufacturing method according to a first embodiment of the present invention will be described using FIGS. 1 to 3. In FIGS. 1 to 3, “11” denotes a GaAs film, which is a semiconductor layer; “12” denotes an AlAs film; “13” denotes an Al₂O₃ film, which is a metal oxide film; and “19” denotes an InGaAs film, which is a thin semiconductor film.

The particle manufacturing method according to this embodiment includes the steps of: forming a resist film or the Al₂O₃ film 13 which is a metal oxide film, on the GaAs substrate 11 which is a semiconductor layer; forming the InGaAs film 19, which is a thin semiconductor film having a thickness approximately equal to the sizes of particles to be formed, on the resist film or the Al₂O₃ film 13 which is a metal oxide film; removing the resist film or the Al₂O₃ film 13 which is a metal oxide film to lift off the InGaAs film 19 which is a thin semiconductor film; and crushing the InGaAs film 19 which is the lifted-off thin semiconductor film.

In the step of forming the metal oxide film, the AlAs film 12 is first deposited on the GaAs substrate 11, and the deposited AlAs film 12 is then oxidized to form the Al₂O₃ film 13 which is a metal oxide film, in the surface of the AlAs film 12. Here, the Al₂O₃ film 13 can be formed by exposing the AlAs film 12 deposited on the semiconductor layer 11 to water vapor at 400° C. to 500° C.

FIG. 1 illustrates a cross-sectional view of the semiconductor layer 11 and the metal oxide film 13. The AlAs film 12 is deposited on the GaAs substrate 11, and the surface of the AlAs film 12 is formed into the Al₂O₃ film 13.

As described above, in the step of forming the metal oxide film, the Al₂O₃ film 13 may be formed by oxidizing the deposited AlAs film 12 in high-temperature water vapor. The Al₂O₃ film 13, which is a metal oxide film, can be efficiently formed by oxidizing the AlAs film 12 in high-temperature water vapor.

Further, using the Al₂O₃ film 13 as a layer to be removed makes it possible to easily remove the Al₂O₃ film 13 which is a metal oxide film, in the step of performing lift-off. Accordingly, it becomes possible to easily manufacture particles to be used in a light-emitting device which emits light of an arbitrary wavelength.

Here, the semiconductor layer 11 is not limited to GaAs. The material thereof may be selected according to the material composition of particles to be manufactured. Using GaAs described in this embodiment as the semiconductor layer 11, particles of GaAs/InGaAs which have quantum well structures can also be manufactured.

Moreover, a method of forming the metal oxide film 13 is not limited. For example, the metal oxide film 13 may be formed by exposing metal deposited on the semiconductor layer 11 to oxygen at approximately 1000° C.

Next, the InGaAs film 19, which is a thin semiconductor film, is deposited on the Al₂O₃ film 13 formed by oxidizing the AlAs film 12.

FIG. 2 illustrates a cross-sectional view of a wafer after the thin semiconductor film 19 has been deposited thereon. The InGaAs film 19 is deposited on the Al₂O₃ film 13 formed on the GaAs substrate 11. The thickness of the InGaAs film 19 deposited is made approximately equal to the sizes of particles. That is, in the case where the sizes of particles are 30 nm, the deposition thickness is approximately 30 nm. In the case where the sizes of particles are 300 nm, the deposition thickness is approximately 300 nm.

Here, the thin semiconductor film 19 may have a quantum well structure. A single quantum well structure may be formed which includes one layer of quantum well structure. A multiple quantum well structure may be formed in which a plurality of quantum well structures are stacked.

It should be noted that a method of forming the quantum well structure is not limited. For example, 2.5 atomic layers of InAs may be grown on a GaAs film smoothed. This makes it possible to form island-shaped quantum dots which are approximately several atomic layers in thickness and approximately several hundreds of atomic layers in diameter, island-shaped quantum dots in which atoms are agglomerated, because of the difference between the lattice constant of InAs and that of the GaAs film.

Then, the Al₂O₃ film 13, which is a metal oxide film, is removed by hydrofluoric acid to lift off the InGaAs film 19.

Also, a method of performing lift-off is not limited. In this embodiment, the Al₂O₃ film 13 is removed by use of hydrofluoric acid. However, for example, using PMMA as the resist film, the PMMA may be removed by acetone to perform lift-off.

Subsequently, the InGaAs film 19, which is a thin semiconductor film lifted off, is crushed by use of ultrasonic waves.

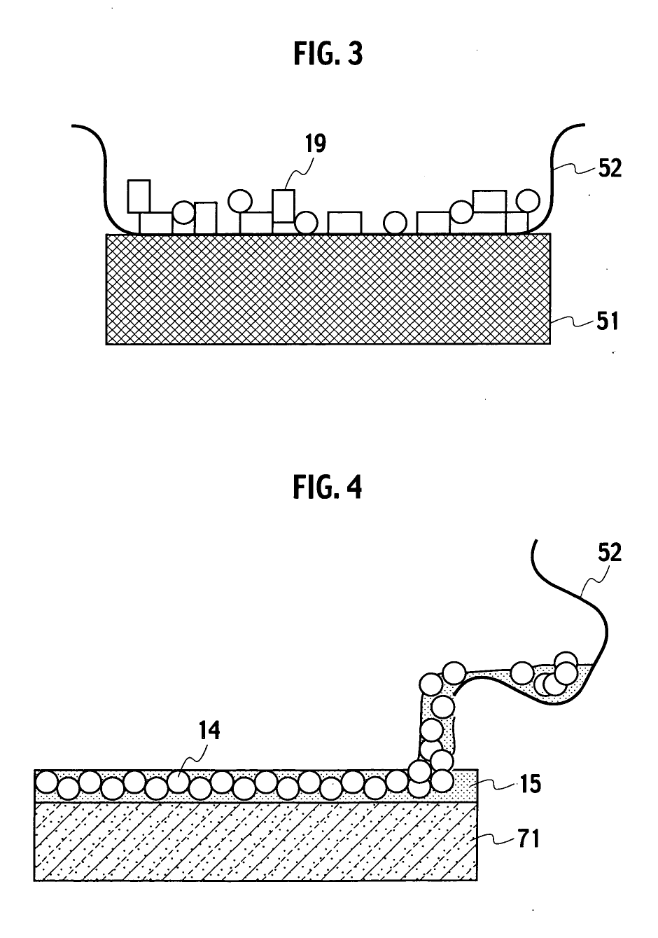

FIG. 3 is a view illustrating one example of a method of crushing the thin semiconductor film by use of ultrasonic waves. In FIG. 3, “51” denotes an ultrasonic vibration table, “52” denotes a vessel, and “19” denotes the InGaAs film, which is a thin semiconductor film. All contents of the vessel 52 are portions of the thin semiconductor film 19.

The lifted-off InGaAs film 19 is placed in the vessel 52 fixed on the ultrasonic vibration table 51, and the ultrasonic vibration table 51 is ultrasonically vibrated. The InGaAs film 19 in the vessel 52 is crushed by the ultrasonic vibration of the ultrasonic vibration table 51 until the InGaAs film 19 becomes particles having sizes approximately equal to the thickness of the InGaAs film 19 deposited on the Al₂O₃ film 13, and thus the InGaAs film 19 is processed into powder.

As described above, in the step of crushing the lifted-off thin semiconductor film 19, the thin semiconductor film 19 may be crushed by use of ultrasonic waves. The crushing of the thin semiconductor film 19 by use of ultrasonic waves makes it possible to form particles having sizes approximately equal to the deposition thickness of the thin semiconductor film 19.

By manufacturing particles having the same size, particles can be manufactured which emit light of a constant wavelength. Further, the control of the thickness of the thin semiconductor film enables light of an arbitrary wavelength to be emitted. Accordingly, it becomes possible to easily manufacture particles to be used in a light-emitting device which emits light of an arbitrary wavelength.

Here, a method of crushing the thin semiconductor film 19 to process it into powders is not limited to ultrasonic vibration. For example, a roll mill may be adopted in which at least two rolls are rotated relative to each other to perform crushing by use of the pressure between the rolls. A cutter mill may be adopted in which a rotary knife is attached to a rotating shaft and in which the rotary knife is rotated to perform crushing. Other than these, a powder processing equipment such as a ball mill, a hammer mill, a disintegrator, or a jet mill may be used.

Further, the thin semiconductor film 19 is not limited to InGaAs. Any of group III-V, II-VI, and VI semiconductors can be used. For example, at least one of AlAs, InP, Si, Ge, C, Se, Zn, ZnS, and ZnO may be used.

As described above, particles having sizes approximately equal to the thickness of the thin semiconductor film can be manufactured by crushing the thin semiconductor film having a thickness approximately equal to the sizes of the particles. Manufacturing the particles alone makes it possible to manufacture a light-emitting device which is not restricted by the lattice constant of a substrate of the light-emitting device. Further, it also becomes possible to manufacture a light-emitting device of an arbitrary wavelength with high yield, by manufacturing particles alone and screening particles to be used in the light-emitting device. Accordingly, it becomes possible to easily manufacture particles to be used in a light-emitting device which emits light of an arbitrary wavelength.

Although a GaAs substrate is used in the above-described embodiment, other substrates may be used. A substrate may be selected according to the material composition and crystal structure of particles. For example, a quantum well structure may be formed by epitaxially growing Ga_{0.78}In_{0.22}N in a nitrogen atmosphere at a growth temperature of 800° C. by MOCVD using a c-plane sapphire substrate and using TB In (tertiary-butyl indium, having a molecular weight of 286) as an In-containing organic compound.

As described above, the formation of particles having an arbitrary material composition and crystal structure becomes possible by: forming a thin semiconductor film for forming the particles on an arbitrary substrate; and lifting off the thin semiconductor film to form the thin semiconductor film into particles.

### SECOND EMBODIMENT

A light-emitting device manufacturing method according to a second embodiment of the present invention will be described. The light-emitting device manufacturing method according to this embodiment includes the steps of: adding particles of semiconductor crystals to a conductive polymer which is a conductive medium having an energy gap larger than those of the particles; interposing the conductive polymer, which is the conductive medium having the particles added thereto in the step of adding particles, between a p-type semiconductor and an n-type semiconductor; and baking the conductive polymer, which is the conductive medium interposed in the interposing step, while applying pressure to the conductive polymer, which is a conductive medium, from both of the p-type and n-type semiconductors.

In the step of adding particles, the particles are added to the conductive polymer which is a conductive medium. The particles are added to the conductive polymer and stirred so as not to be unevenly distributed in the conductive polymer.

It should be noted that, in the step of adding particles, the particles of semiconductor crystals may be added to the conductive polymer liquefied. Use of the conductive polymer liquefied makes it possible to densely fill spaces between the independently manufactured particles with the conductive medium and to manufacture a particle layer in which the particles are distributed approximately evenly. Accordingly, it becomes possible to easily manufacture a light-emitting device which emits light of an arbitrary wavelength.

Also, as the particles, the particles manufactured by crushing the thin semiconductor film 19, which have been described in the aforementioned first embodiment, can be used. However, the particles are not limited to these. Any particles can be used as long as they are microcrystals made of a semiconductor which have a desired material composition and size. For example, it is also possible to use columnar crystals which have diameters equal to the sizes of the particles and which have been grown to be equal in thickness to the sizes of the particles.

Further, the amount of the particles added to the conductive polymer is not limited. For example, the volume ratio of the conductive polymer to the particles may be 10 to 1. If the amount of the particles added to the conductive polymer is small, the efficiency of recombination radiation in the particles can be increased even when the amounts of positive holes and electrons supplied are small. If the amount of the particles is increased, the amount of light emitted by recombination can be increased by increasing the amounts of positive holes and electrons supplied.

In the interposing step, the conductive polymer having the particles added thereto is applied to the surface of the p-type semiconductor. FIG. 4 is a view for explaining a situation in which the conductive medium having the particles added thereto is applied to the surface of the p-type or n-type semiconductor. In FIG. 4, “14” denotes a particle; “15” denotes the conductive polymer, which is a conductive medium; “71” denotes the p-type semiconductor; and “52” denotes a vessel which contains the conductive polymer 15 having the particles 14 added thereto.

In FIG. 4, the conductive polymer 15 having the particles 14 added thereto is applied to the surface of the p-type semiconductor 71. The conductive polymer 15 having the particles 14 added thereto is poured on and applied to the surface of the p-type semiconductor 71 formed on a substrate.

Then, the n-type semiconductor is further deposited on the applied conductor polymer 15 having the particles 14 added thereto. As the n-type semiconductor, one formed on a substrate different from that of the p-type semiconductor may be used.

Here, in this interposing step, the conductive polymer, which is the conductive medium having the particles added thereto, may be applied to the surface of the p-type or n-type semiconductor by means of spin coating. By applying the conductive medium having the particles added thereto by means of spin coating, the conductive medium can be applied to the surface of the p-type or n-type semiconductor so as to have an even thickness. Evenly applying the conductive medium facilitates distributing the particles in the conductive medium approximately evenly. By distributing the particles in the conductive medium approximately evenly, the distribution of the particles provided in an individual chip diced can be made approximately even. Accordingly, a light-emitting device which emits light of an arbitrary wavelength can be manufactured so as to be homogeneous.

Also, in the interposing step, a method of interposing, between the p-type and n-type semiconductors, the conductive medium having the particles added thereto is not limited. For example, it is acceptable to provide a space by placing spacers between the p-type and n-type semiconductors and to fill the space with the conductive medium having the particles added thereto. The filling can be performed by utilizing surface tension or by vacuum suction.

Further, in the interposing step, the p-type and n-type semiconductors have been separately formed, but other method is also acceptable. The n-type semiconductor may be further deposited on the applied conductor polymer.

In the baking step, the conductive polymer having the particles added thereto is baked at 300° C. while pressure is being applied to the conductive polymer from both of the p-type and n-type semiconductors. Thus, a particle layer can be formed. Here, the temperature at which the conductive polymer is baked is not limited to 300° C. The conductive polymer can be baked at appropriate temperatures according to the material composition of the conductive medium.

Note that the p-type and n-type semiconductors are equivalent to the p-type and n-type semiconductor layers 16 and 17 illustrated in FIG. 5, which will be described in a third embodiment.

As described above, it becomes possible to manufacture a light-emitting device using, as components of the light-emitting device, particles of semiconductor crystals which have been manufactured by a process independent of that for the light-emitting device. This makes it possible to use an arbitrary material composition which is not restricted by a substrate of the light-emitting device, and to manufacture a light-emitting device which enables energy gap control using a quantum effect. Accordingly, it becomes possible to provide a light-emitting device which emits light of an arbitrary wavelength.

### THIRD EMBODIMENT

A light-emitting device according to a third embodiment of the present invention will be described using FIG. 5. FIG. 5 is a cross-sectional view of the light-emitting device according to this embodiment. In FIG. 5, “14” denotes a particle of a semiconductor crystal; “15” denotes a conductive polymer, which is a conductive medium; “16” denotes a p-type semiconductor layer; “17” denotes an n-type semiconductor layer; and “18” denotes a particle layer. The particle layer 18 is placed on the p-type semiconductor layer 16, and the n-type semiconductor layer 17 is placed on the particle layer 18. The particle layer 18 has a constitution in which a plurality of particles 14 are scattered in the conductive polymer 15.

The p-type semiconductor layer 16 is a layer made of a semiconductor in which current carriers are mainly positive holes. The p-type semiconductor layer 16 is not limited as long as positive holes can be moved with the application of a voltage. For example, it is possible to use, as the p-type semiconductor layer 16, one obtained by adding, to Si which is a group IV semiconductor, a group III semiconductor such as B, Al, Ga, In, and Tl as an impurity.

The n-type semiconductor layer 17 is a layer made of a semiconductor in which current carriers are mainly electrons. The n-type semiconductor layer 17 is not limited as long as electrons can be moved by the application of a voltage. For example, it is possible to use, as the n-type semiconductor layer 17, one obtained by adding, to Si which is a group IV semiconductor, a group V semiconductor such as P, As, Sb, or Bi as an impurity.

The particle layer 18 is a layer including particles 14 of semiconductor crystals and the conductive medium 15 filling spaces between the particles 14. The particle layer 18 may be any layer as long as it has a structure in which a plurality of particles 14 are provided in the conductive medium 15. The arrangement of the particles 14 provided in the particle layer 18 is not limited. For example, in the case of the light-emitting device manufacturing method described in the aforementioned second embodiment, the particles 14 are arranged at random in the conductive medium 15. For example, in the case where a current confinement structure is formed between the p-type and n-type semiconductor layers 16 and 17, the particles 14 may be arranged intensively in portions to which positive holes and electrons are supplied.

Further, the thickness of the particle layer 18 is not limited. For example, a light-emitting layer may be formed which has a thickness of not less than 300 nm and includes the particles 14 having sizes of 300 nm in the particle layer 18. Moreover, even in the case where the particles 14 having sizes of not more than 10 nm are provided, a light-emitting layer having a thickness of not less than 300 nm may be formed. Thus, the thickness of the particle layer 18 can be arbitrarily selected. However, in the case where the thickness of the particle layer 18 is increased, the distance over which positive holes and electrons are transported increases. This can be dealt with by increasing the carrier density of the conductive medium 15.

The particles 14 are semiconductor crystals for confining positive holes and electrons to allow the occurrence of recombination radiation. The energy gaps of the particles 14 are smaller than that of the conductive polymer 15. The particles 14 do not need to be complete semiconductor crystals, but may be ones obtained by crushing a semiconductor crystal into particles, such as the particles described in the aforementioned first embodiment.

Further, since the particles are semiconductor crystals, the size of each particle 14 is preferably larger than that of the unit cell of a semiconductor crystal. For example, in terms of the unit cell of a semiconductor crystal, the size of GaAs is approximately 0.56 nm, and that of Si is 0.54 nm. Thus, the sizes of the particles are preferably not less than approximately 0.5 nm.

Moreover, the sizes of the particles 14 are preferably not more than 300 nm. The particles 14 having sizes of not more than 300 nm makes it possible to improve the efficiency of recombination radiation by confining positive holes and electrons by dint of energy gaps.

In this case, light of an arbitrary wavelength can be emitted by changing the material composition of the particles 14. Further, in the case where each particle 14 has a quantum well structure, the wavelength of light emitted by recombination can also be changed by the quantum well structure. Accordingly, it becomes possible to provide a light-emitting device which emits light of an arbitrary wavelength.

Further, the sizes of the particles 14 may be not more than 100 nm. The particles having sizes of not more than 100 nm makes it possible to further improve the efficiency of recombination radiation by confining positive holes and electrons by dint of energy gaps.

In this case, light of an arbitrary wavelength can be emitted by changing the material composition of the particles 14. Further, in the case where each particle 14 has a quantum well structure, the wavelength of light emitted by recombination can also be changed by the quantum well structure. Accordingly, it becomes possible to provide a light-emitting device which emits light of an arbitrary wavelength.

Further, the sizes of the particles 14 may be not more than 30 nm. The particles 14 having sizes of not more than 30 nm makes it possible to confine positive holes and electrons to allow the occurrence of recombination radiation, because of a quantum effect which occurs according to the sizes of the particles. That is, light of an arbitrary wavelength can be emitted by changing the sizes of the particles. Accordingly, it becomes possible to provide a light-emitting device which emits light of an arbitrary wavelength.

Moreover, the sizes of the particles 14 may be not more than the de Broglie wavelengths of an electron and a positive hole. That is, the particles 14 may have sizes with which a quantum confinement effect manifests. The particles 14 having sizes with which a quantum confinement effect manifests enable a quantum well structure to be formed according to the sizes of the particles 14. An arbitrary energy gap can be formed by changing the sizes of the particles. Accordingly, it becomes possible to provide a light-emitting device which emits light of an arbitrary wavelength.

Furthermore, each particle 14 preferably has a quantum well structure. The quantum well structure of the particle 14 is not limited. The quantum well structure is arbitrary as long as it has the effect of confining positive holes and electrons by virtue of the structure.

For example, in particular, if the sizes of the particles are not more than 10 nm, positive holes and electrons can be confined according to the sizes of the particles. For example, each particle 14 may have a multiple quantum well structure in which a plurality of quantum well structures are stacked.

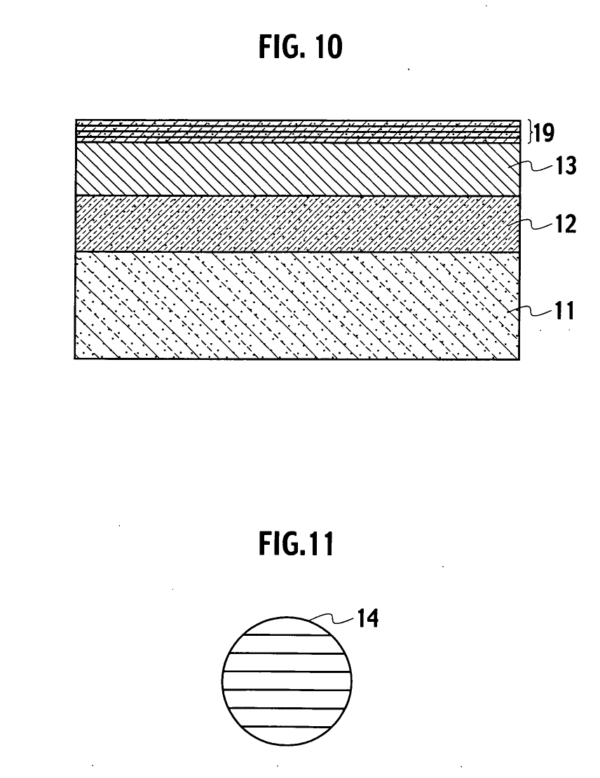

Specifically, in the particle manufacturing method according to the aforementioned first embodiment, if the InGaAs film 19 is formed so as to have a multiple quantum well structure as illustrated in FIG. 10, each particle 14 manufactured has a multiple quantum well structure as illustrated in FIG. 11. Further, in the particle manufacturing method according to the aforementioned first embodiment, the particles 14 manufactured may be surface treated by use of a predetermined method.

Thus, the particles 14 having multiple quantum well structures enable the effect to be improved, the effect being of confining positive holes and electrons in the particles regardless of the sizes of the particles 14. Further, the particles 14 having quantum well structures also makes it possible to change the wavelength of light emitted by recombination. Accordingly, it becomes possible to provide a light-emitting device which has an improved emission efficiency and which emits light of an arbitrary wavelength.

The particles 14 are preferably made of GaAs/InGaAs, AlAs/InGaAs, or InP/InGaAs. In the case where the particles are made of GaAs/InGaAs, AlAs/InGaAs, or InP/InGaAs, crystal growth is easy. Thus, it becomes possible to easily form particles having quantum well structures. Accordingly, it becomes possible to provide a light-emitting device which is easily manufactured and which emits light of an arbitrary wavelength.

It should be noted that the material of the particles 14 is not limited to the above-described ones. As the material of the particles 14, any of group III-V, II-VI, and VI semiconductors can be used. For example, as the material of the particles 14, at least any one of AlAs, InP, Si, Ge, C, Se, Zn, ZnS, and ZnO may be used.

Further, each particle 14 may be made of a plurality of semiconductor crystals. For example, each particle 14 may be one in which a plurality of two types of semiconductor crystals, InGaAs and GaAs, are stacked. It is also possible to use a particle which has a diameter of approximately 55 nm and in which three quantum well layers are formed by use of layers of InGaAs and GaAs.

The conductive polymer 15 is a conductive medium. The conductive polymer 15 fills spaces between the particles of semiconductor crystals, and transports positive holes and electrons supplied to the particle layer 18. The conductive polymer 15 has an energy gap larger than those of the particles 14.

It should be noted that the conductive medium is preferably made of a conductive polymer. The conductive polymer 15 has conductivity by itself. The conductive medium made of a conductive polymer enables the particle layer to be formed by adding the particles to the conductive polymer liquefied. This makes it possible to easily form the particle layer. Accordingly, it becomes possible to provide a light-emitting device which is easily manufactured and which emits light of an arbitrary wavelength.

The material of the conductive polymer is not limited. Conductive polymers include, for example, hydrocarbon conductive polymers such as polyacetylene, polyazulene, polyphenylene vinylene, polyacene, and polydiacetylene; heteroatom-containing conductive polymers such as polypyrrole, polyaniline, polythiophene, and polythienylene vinylene; tertiary aromatic amines; bis(diarylamino)anthracene; tetrahydronaphthalene; acridine; dibenzoazepinylbenzene derivatives; and compounds having iminostilbene skeletons.

The carrier density of the conductive medium 15 may be not less than 10¹⁴ nor more than 10¹⁷ (cm⁻³). That is, the concentration of an acceptor impurity which produces positive holes and the concentration of a donor impurity which produces electrons may be not less than 10¹⁴ nor more than 10¹⁷ (cm⁻³) The conductive medium having a carrier density of not less than 10¹⁴ nor more than 10¹⁷ (cm⁻³) makes it possible to improve the efficiency with which positive holes and electrons supplied are transported to the particles. Accordingly, it becomes possible to provide a light-emitting device which has an improved emission efficiency and which emits light of an arbitrary wavelength.

However, the carrier density of the conductive medium according to the present invention is not limited to this. The amount of positive holes and electrons transported can be changed by changing the carrier density of the conductive medium.

The operation of the light-emitting device according to this embodiment will be described using FIG. 5.

First, a voltage is applied between the p-type and n-type semiconductor layers 16 and 17. By the application of the voltage, positive holes of the p-type semiconductor layer 16 are moved, and the particle layer 18 is supplied with positive holes. Further, by the application of the voltage, electrons of the n-type semiconductor layer 17 are moved, and the particle layer 18 is supplied with electrons. Each positive hole supplied to the particle layer 18 is transported toward the n-type semiconductor layer 16 through the conductive polymer 15, and is confined, during the transportation, in any one of the plurality of particles 14 distributed in the conductive polymer 15 of the particle layer 18. Each electron supplied to the particle layer 18 is transported toward the p-type semiconductor layer 17 through the conductive polymer 15, and is confined, during the transportation, in any one of the plurality of particles 14 distributed in the conductive polymer 15 of the particle layer 18.

As described above, positive holes and electrons are confined in the particles 14 distributed in the particle layer 18, thereby causing recombination radiation.

If the particles 14 of semiconductor crystals are distributed in the conductive medium polymer 15, an arbitrary material composition which is not limited by a substrate of a light-emitting device can be used, and energy gap control using a quantum effect can be performed, because a confining energy gap can be formed in each particle 14. Accordingly, it becomes possible to provide a light-emitting device which emits light of an arbitrary wavelength.

Although in the aforementioned third embodiment, “16” is the p-type semiconductor layer and “17” is the n-type semiconductor layer as illustrated in FIG. 5, “16” may be replaced by a positive hole supply layer which supplies positive holes, and “17” maybe replaced by an electron supply layer which supplies electrons.

The positive hole supply layer is intended to supply positive holes to the particle layer 18 by the application of a voltage. The electron supply layer is intended to supply electrons to the particle layer 18 by the application of a voltage. That is, both of the positive hole supply layer and the electron supply layer are not limited to semiconductors.

For example, the metals of the positive hole supply layer and the electron supply layer may be conductive ceramic such as alumina ceramic, conductive plastic such as plastic mixed with tin alloy, or a conductive polymer.

Since energy gaps are formed by the particles of semiconductor crystals and the conductive medium, a light-emitting device can also be formed using, for the positive hole supply layer and the electron supply layer, a material composition as described above. Accordingly, it becomes possible to provide a light-emitting device which emits light of an arbitrary wavelength.

Further, in the aforementioned third embodiment, as illustrated in FIG. 5, “16” is the p-type semiconductor layer, and “17” is the n-type semiconductor layer. However, the arrangement of the p-type and n-type semiconductor layers and the particle layer is not limited to this.

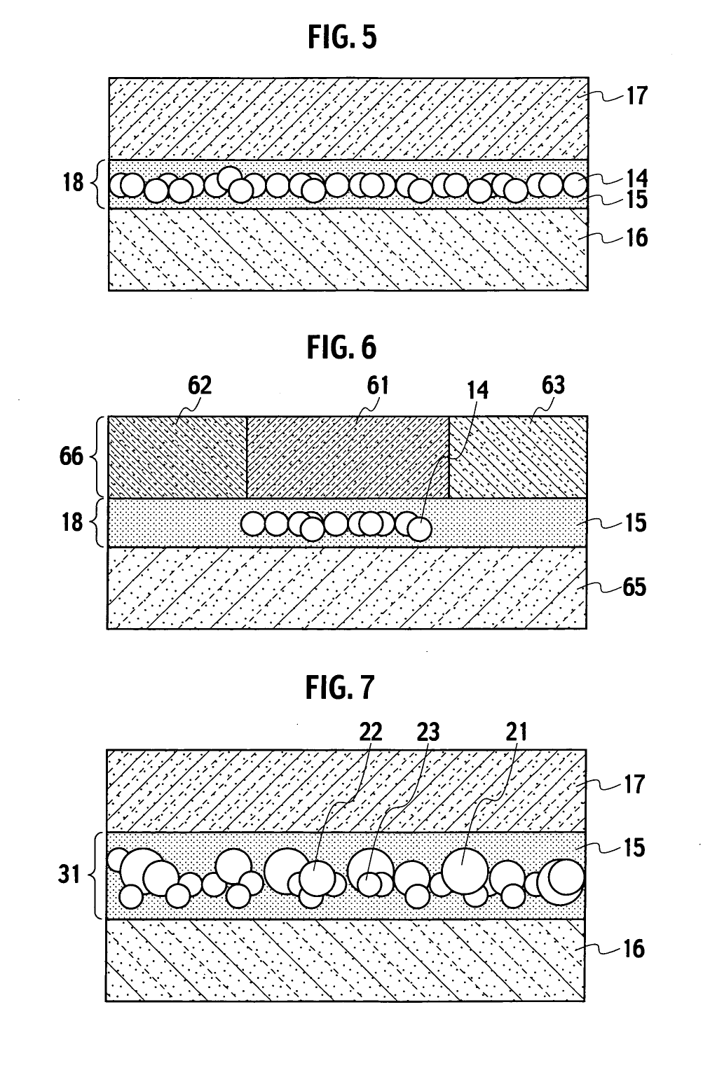

For example, as illustrated in FIG. 6, an intrinsic semiconductor layer in which p-type and n-type semiconductor portions are placed at a distance from each other, and the particle layer 18 may be provided. FIG. 6 is a cross-sectional view of a light-emitting device according to this example.

In FIG. 6, “14” denotes a particle, “15” denotes a conductive medium, “18” denotes a particle layer, “61” denotes an intrinsic semiconductor portion, “62” denotes a p-type semiconductor portion, “63” denotes an n-type semiconductor portion, “65” denotes a substrate, and “66” denotes an intrinsic semiconductor layer. The particle layer 18 is placed on the substrate 65, and the intrinsic semiconductor layer 66 is placed on the particle layer 18. In the intrinsic semiconductor layer 66, the p-type and n-type semiconductor portions 62 and 63 are formed away from each other. That is, in the intrinsic semiconductor layer 66, the p-type semiconductor portion 62, the intrinsic semiconductor portion 61, and the n-type semiconductor portion 63 are placed in this order in a direction perpendicular to the stacking direction of the substrate 65.

Such a constitution also allows the p-type semiconductor portion 62 to supply positive holes to the particle layer 18 and allows the n-type semiconductor portion 63 to supply electrons to the particle layer 18. Thus, the conductive medium 15 can transport positive holes and electrons to allow the occurrence of recombination radiation in the particles 14 distributed in the conductive medium 15.

Further, in the light-emitting device illustrated in FIG. 5, the n-type semiconductor layer 17, the particle layer 18, and the p-type semiconductor layer 16 are arranged in this order. However, other layers may be placed between these layers. For example, a shield layer, which partially and selectively prevents positive holes and electrons from moving to achieve current confinement, may be provided in at least any one of a space between the n-type semiconductor layer 17 and the particle layer 18 and a space between the p-type semiconductor layer 16 and the particle layer 18. Further, the particle layer may be partially and selectively etched to achieve current confinement.

Moreover, the conductive medium 15 is a conductive polymer in this embodiment, but is not limited to this. The conductive medium 15 may be any medium as long as it has an energy gap larger than those of the particles 14 of semiconductor crystals.

For example, the conductive medium 15 maybe a group III-V, II-VI, or IV semiconductor. In this case, the particles 14 may be added to an atmosphere of the conductive medium 15 during the time that the conductive medium 15 is being grown by use of MOCVD. Further, as the conductive medium 15, plastic having conductivity due to an additive agent or the like may be used. Moreover, as the conductive medium 15, ZnO-based materials, IDIXO, or indium tin oxide (ITO) may be used.

Further, the conductive polymer 15 preferably has an energy gap smaller than those of layers between which the particle layer 18 is interposed. The particle layer 18 having an energy gap smaller than those of layers on both sides thereof enables positive holes and electrons to be confined in the particle layer.

### FOURTH EMBODIMENT

The particle layer 18 described using the aforementioned FIG. 5 may have particles having different sizes and/or material compositions. A cross-sectional view of a light-emitting device according to this embodiment is illustrated in FIG. 7. In FIG. 7, “15” denotes a conductive medium; “16” denotes a p-type semiconductor layer; “17” denotes an n-type semiconductor layer; “21”, “22” and “23” denote particles; and “31” denotes a particle layer. As in FIG. 5, the particle layer 31 is interposed between the p-type and n-type semiconductor layers 16 and 17.

A difference with FIG. 5 is the sizes of the particles provided in the particle layer 31. The particle layer 31 of this embodiment includes particles 21, 22 and 23 having three different sizes. Each of the particles 21, 22 and 23 is smaller than 10 nm. Further, the particles 21, 22 and 23 are different in size. The particles 21 are the largest, and the particles 22 are larger than the particles 23. The particles 21, 22 and 23 are distributed at random in the conductive medium 15.

Positive holes and electrons supplied to the particle layer 31 are confined in the particles 21, 22 and 23, and recombine to emit light in the respective particles 21, 22 and 23. This enables light of wavelengths according to the respective energy gaps of the particles 21, 22 and 23 to be emitted. Since each of the particles 21, 22 and 23 is smaller than 10 nm, the wavelengths of light emitted by recombination can be controlled according to the sizes thereof.

Although the particles 21, 22 and 23 are assumed to be smaller than 10 nm and different in size, they are not limited to sizes of less than 10 nm. Further, the particles 21, 22 and 23 may be different in material composition. The difference in material composition makes it possible to separately change the respective energy gaps of the particles 21, 22 and 23. This enables light of wavelengths according to the respective energy gaps of the particles 21, 22 and 23 to be emitted. Furthermore, the emission wavelengths can be changed by changing the combination of the material compositions and sizes of the particles 21, 22 and 23. Note that the number of types of energy gaps is not limited to three, but may be two, four or more.

As described above, the provision of particles having different sizes and/or material compositions in the particle layer enables light of a plurality of wavelengths to be emitted from one particle layer. This makes it possible to control the emission wavelengths to an arbitrary spectral width and an arbitrary central wavelength. Accordingly, it becomes possible to provide a light-emitting device which emits light of an arbitrary spectral width and arbitrary wavelengths.

As in the above-described fourth embodiment, lights emitted in the particles 21, 22 and 23 having different sizes and/or material compositions can be mixed into white light by virtue of additive color mixture. For example, the particles 21 are caused to emit red light, the particles 22 are caused to emit green light, and the particles 23 are caused to emit blue light.

In this case, recombination radiation occurs more frequently in the particles 21 which have smaller energy gaps and emit red light. Accordingly, color bias can be corrected by distributing a larger amount of particles 23 which emit blue light. Thus, mixing the emitted lights into white light by of additive color mixture enables white light to be emitted from one light-emitting device.

### FIFTH EMBODIMENT

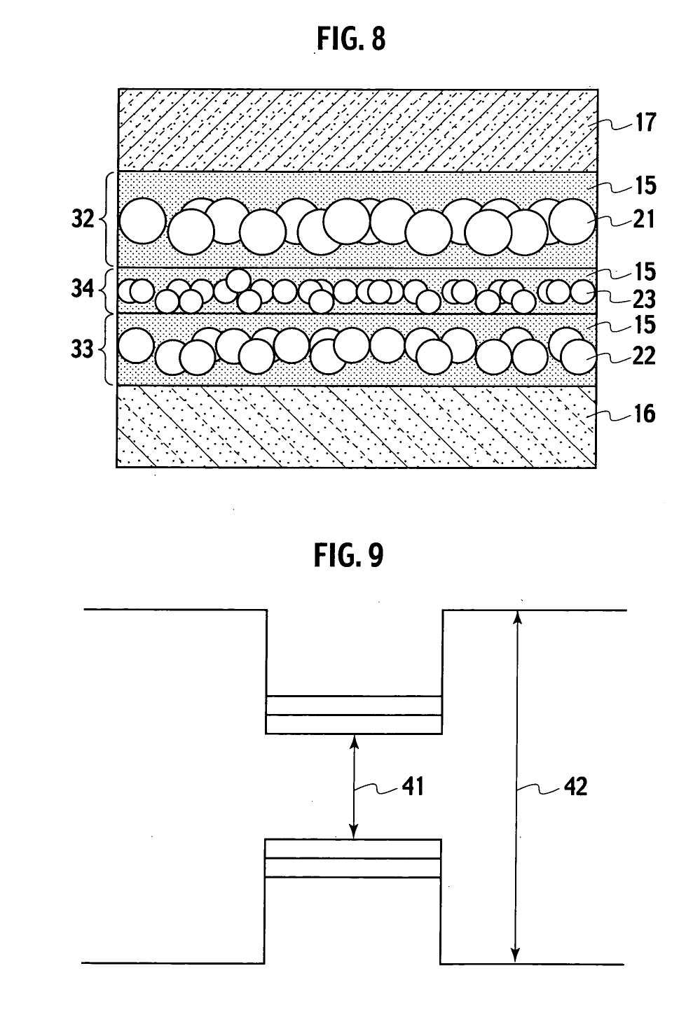

The particle layer 18 described using the aforementioned FIG. 5 may include a plurality of layers which have particles having different sizes and/or material compositions, respectively. A cross-sectional view of a light-emitting device according to this embodiment is illustrated in FIG. 8. In FIG. 8, “15” denotes a conductive medium; “16” denotes a p-type semiconductor layer; “17” denotes an n-type semiconductor layer; “21”, “22” and “23” denote particles; and “32”, “33” and “34” denote particle layers. As in FIG. 5, the particle layers 32, 33 and 34 are interposed between the p-type and n-type semiconductor layers 16 and 17.

In the light-emitting device illustrated in FIG. 8, the particle layers 33, 34 and 32 are interposed in this order between the p-type and n-type semiconductor layers 16 and 17. The particle layer 32 includes the particles 21. The particle layer 33 includes the particles 22. The particle layer 34 includes the particles 23. As in FIG. 7, each of the sizes of the particles 21, 22 and 23 is smaller than 10 nm. Further, the particles 21, 22 and 23 are different in size. The particles 21 are the largest, and the particles 22 are larger than the particles 23. In each of the particle layers 32, 33 and 34, spaces between particles are filled with the conductive medium 15.

Electrons, which are supplied to the particle layer 32, and positive holes, which are supplied through the particle layers 33 and 34 to the particle layer 32, are confined in the particles 21 and recombine to emit light in the particles 21. Electrons, which are supplied through the particle layer 32 to the particle layer 34, and positive holes, which are supplied through the particle layer 33 to the particle layer 33, are confined in the particles 23 and recombine to emit light in the particles 23. Electrons, which are supplied through the particle layers 32 and 34 to the particle layer 33, and positive holes, which are supplied to the particle layer 33, are confined in the particles 22 and recombine to emit light in the particles 22.

This enables lights of wavelengths according to the respective energy gaps of the particles 21, 22 and 23 to be emitted from the particle layers 32, 33 and 34, respectively.

Although the particles 21, 22 and 23 are assumed to be smaller than 10 nm and different in size, none of the sizes thereof is limited to a size of less than 10 nm. Further, the particles 21, 22 and 23 maybe different in material composition. The difference in material composition makes it possible to separately change the respective energy gaps of the particles 21, 22 and 23. This enables light of wavelengths according to the respective energy gaps of the particles 21, 22 and 23 to be emitted. Furthermore, the emission wavelengths can be changed by changing the combination of the material compositions and sizes of the particles 21, 22 and 23.

Further, the amount of positive holes and electrons supplied to each particle layer can be adjusted by changing the carrier density of the conductive medium 15 provided in the particle layer.

As described above, the provision of particles having different sizes and/or material compositions in the respective layers enables lights of different wavelengths to be emitted from the layers, respectively. This makes it possible to control the emission wavelengths to an arbitrary spectral width and an arbitrary central wavelength.

Moreover, since one particles of one type are distributed in one layer, the manufacture of a light-emitting device becomes easy compared to that for the case where a plurality of types of particles are scattered in one particle layer. Accordingly, it becomes possible to provide a light-emitting device which emits light of an arbitrary spectral width and an arbitrary wavelength.

It should be noted that lights emitted in the particles 21, 22 and 23 having different sizes and/or material compositions can be mixed into white light by virtue of additive color mixture. For example, the particles 21 emit red light, the particles 22 emit green light, and the particles 23 emit blue light.

In this case, recombination radiation more frequently occurs in the particles 21 which have smaller energy gaps and emit red light. Accordingly, color bias can be corrected by distributing a larger amount of particles 23 which emit blue light. Thus, mixing the emitted lights into white light by virtue of additive color mixture enables white light to be emitted from one light-emitting device. Accordingly, it becomes possible to provide a light-emitting device which produces light of arbitrary wavelengths.

As described previously, a light-emitting device according to the present invention has a structure in which spaces between particles made of semiconductor crystals are filled with a conductive medium having an energy gap larger than those of the particles. FIG. 9 illustrates an example of the energy gaps of the conductive medium and a particle. In FIG. 9, “41” denotes the energy gap of a particle, and “42” denotes the energy gap of the conductive medium.

In a particle layer provided in the light-emitting device according to the present invention, as illustrated in FIG. 9, a conductive medium having an energy gap 42 larger than the energy gap 41 of each particle surrounds particles. This makes it possible to efficiently confine positive holes and electrons in the particles.

A plurality of particles in such states are distributed in the conductive medium, and positive holes and electrons supplied to the conductive medium are confined in the particles. This makes it possible to efficiently cause recombination radiation.

Further, if particles of semiconductor crystals are contained in the conductive medium, energy gaps which enable positive holes and electrons to be confined can be formed in the particles. Accordingly, a semiconductor layer for confining positive holes and electrons does not need to be deposited on a substrate. This makes it possible to form energy gaps for confining positive holes and electrons without being limited by the lattice constant of a substrate of a light-emitting device.

Accordingly, a light-emitting device which emits light of an arbitrary wavelength can be provided by combining arbitrary material compositions. Further, the energy gaps formed in the particles of semiconductor crystals are formed depending on the combination of the material composition of the particles and that of the conductive medium. Accordingly, it also becomes possible to cause recombination radiation at energy larger than the energy gap of the material composition of the particles.

Further, if the particles are manufactured by use of a process independent of that for depositing layers of a light-emitting device as described previously, it becomes possible to use particles having even sizes of several nm for a light-emitting device. Accordingly, since the evenness of particles of several nm can be ensured, energy gaps can be controlled according to the sizes of the particles using a quantum effect. Thus, it becomes possible to provide a light-emitting device which emits light of an arbitrary wavelength according to the sizes of the particles.

Specifically, the light-emitting device according to the present invention includes: a positive hole supply layer; a particle layer having particles of semiconductor crystals and a conductive medium which fills spaces between the particles and which confines positive holes and electrons in the particles by an energy gap larger than those of the particles; and an electron supply layer, in this order. Positive holes, which are supplied from the positive hole supply layer through the conductive medium to the particles, and electrons, which are supplied from the electron supply layer through the conductive medium to the particles, are caused to recombine to emit light in the particles.

Here, the positive hole supply layer is configured so as to supply positive holes by use of the application of a voltage, and the electron supply layer is configured so as to supply electrons by use of the application of a voltage. Further, the conductive medium of the particle layer is configured so as to transport, to the particles of semiconductor crystals, the positive holes supplied from the positive hole supply layer and the electrons supplied from the electron supply layer. Moreover, the particles of semiconductor crystals are configured so as to confine the transported positive holes and electrons and allow the occurrence of recombination radiation.

As a result, energy gaps are formed by the particles of semiconductor crystals and the conductive medium. Accordingly, an arbitrary material composition can be used which is not limited by a substrate of the light-emitting device, and energy gaps can be controlled using a quantum effect. Thus, it becomes possible to provide a light-emitting device which emits light of an arbitrary wavelength.

Another light-emitting device according to the present invention includes: a p-type semiconductor layer; a particle layer having particles of semiconductor crystals and a conductive medium which fills spaces between the particles and which confines positive holes and electrons in the particles by an energy gap larger than those of the particles; and an n-type semiconductor layer, in this order. Positive holes, which are supplied from the p-type semiconductor layer through the conductive medium to the particles, and electrons, which are supplied from the n-type semiconductor layer through the conductive medium to the particles, are caused to recombine to emit light in the particles.

The particle layer allows positive holes and electrons supplied from the p-type and n-type semiconductor layers to recombine and emit light, in the particles. Accordingly, since energy gaps are formed by the particles of semiconductor crystals and the conductive medium, an arbitrary material composition can be used which is not limited by a substrate of the light-emitting device, and energy gaps can be controlled using a quantum effect. Thus, it becomes possible to provide a light-emitting device which emits light of an arbitrary wavelength.

The sizes of the particles may be not more than the de Broglie wavelengths of an electron and a positive hole. The particles having sizes of not more than the de Broglie wavelengths enable a quantum well structure to be formed according to the sizes of the particles. Thus, an arbitrary energy gap can be formed by changing the sizes of the particles. Accordingly, it becomes possible to provide a light-emitting device which emits light of an arbitrary wavelength according to the sizes of particles.

The particles may have sizes with which a quantum confinement effect manifests. The particles having sizes with which a quantum confinement effect manifests enable a quantum well structure to be formed according to the sizes of the particles. Thus, an arbitrary energy gap can be formed by changing the sizes of the particles. Accordingly, it becomes possible to provide a light-emitting device which emits light of an arbitrary wavelength according to the sizes of particles.

The sizes of the particles may be not more than 300 nm, preferably not more than 100 nm, more preferably not more than 30 nm, and may be not less than 0.5 nm.

The particles having sizes of not more than 300 nm makes it possible to improve the efficiency of recombination radiation by confining positive holes and electrons by dint of energy gaps. Further, the particles having sizes of not more than 100 nm makes it possible to further improve the efficiency of recombination radiation by confining positive holes and electrons by dint of energy gaps. Furthermore, the particles having sizes of not more than 30 nm makes it possible to confine positive holes and electrons to allow the occurrence of recombination radiation, because of a quantum effect which occurs according to the sizes of the particles. That is, light of an arbitrary wavelength can be emitted by changing the sizes of the particles.

Further, the sizes of the particles may be not less than 0.5 nm. Since the particles are semiconductor crystals, the sizes thereof are preferably not less than approximately 0.5 nm which is equivalent to the size of the unit cell of a semiconductor crystal.

The particles may have quantum well structures. The particles having multiple quantum well structures enable the effect of confining positive holes and electrons in the particles to be improved. Accordingly, it becomes possible to provide a light-emitting device which has an improved emission efficiency and which emits light of an arbitrary wavelength.

The carrier density of the conductive medium may be not less than 10¹⁴ nor more than 10¹⁷ (cm⁻³) . That is, the concentration of an acceptor impurity which produces positive holes and the concentration of a donor impurity which produces electrons may be not less than 10¹⁴ nor more than 10¹⁷ (cm⁻³). The conductive medium having a carrier density of not less than 10¹⁴ nor more than 10¹⁷ (cm⁻³) makes it possible to improve the efficiency with which positive holes and electrons supplied to the particle layer are transported to the particles. Accordingly, it becomes possible to provide a light-emitting device which has an improved emission efficiency and which emits light of an arbitrary wavelength.

The particle layer may have particles having different sizes and/or material compositions. The provision of particles having different sizes and/or material compositions in the particle layer enables light of a plurality of wavelengths to be emitted from one particle layer. This makes it possible to control light so that the light is emitted with an arbitrary spectral width and at an arbitrary central wavelength. Accordingly, it becomes possible to provide a light-emitting device which produces light of an arbitrary spectral width and arbitrary wavelengths.

The particle layer may include a plurality of layers which have particles having different sizes and/or material compositions, respectively. The provision of particles having different sizes and/or material compositions in the respective layers enables lights of different wavelengths to be emitted from the layers, respectively. This makes it possible to control the emission wavelengths to an arbitrary spectral width and an arbitrary central wavelength. Accordingly, it becomes possible to provide a light-emitting device which emits light of an arbitrary spectral width and arbitrary wavelengths.

In the case where light of a plurality of wavelengths is emitted, lights emitted in the particles having different sizes and/or material compositions can be mixed into white light by virtue of additive color mixture. By mixing the lights emitted from the particles having different sizes and/or material compositions into white light by virtue of additive color mixture, white light can be emitted from one light-emitting device. Accordingly, it becomes possible to provide a light-emitting device which emits white light by itself.

The particles may be made of GaAs/InGaAs, AlAs/InGaAs, or InP/InGaAs. In the case where the particles are formed so that the material composition thereof becomes GaAs-based one: GaAs/InGaAs, AlAs/InGaAs, or InP/InGaAs, crystal growth is easy. Thus, it becomes possible to easily form particles having quantum well structures. Accordingly, it becomes possible to provide a light-emitting device which is easily manufactured and which emits light of an arbitrary wavelength.

The conductive medium may be made of a conductive polymer. The conductive medium made of a conductive polymer enables the particle layer to be formed by adding the particles to the conductive polymer liquefied. This makes it possible to easily form the particle layer. Accordingly, it becomes possible to provide a light-emitting device which is easily manufactured and which emits light of an arbitrary wavelength.

As described previously, a particle manufacturing method according to the present invention includes the steps of: forming a resist film or a metal oxide film on a semiconductor layer; forming a thin semiconductor film having a thickness approximately equal to the sizes of particles to be formed, on the resist film or the metal oxide film; removing the resist film or the metal oxide film to lift off the thin semiconductor film; and crushing the lifted-off thin semiconductor film by use of ultrasonic waves.

Particles having sizes approximately equal to the thickness of the thin semiconductor film can be manufactured by crushing the thin semiconductor film having a thickness approximately equal to the sizes of the particles. Manufacturing the particles alone makes it possible to manufacture a light-emitting device which is not restricted by a substrate of the light-emitting device. Further, manufacturing particles alone makes it possible to manufacture particles having arbitrary sizes and to screen the particles according to size. Thus, it becomes possible to manufacture a light-emitting device of an arbitrary wavelength with high yield. Accordingly, it becomes possible to easily manufacture particles to be used in a light-emitting device which emits light of an arbitrary wavelength.

In the step of forming the metal oxide film, AlAs deposited may be oxidized in high-temperature water vapor to form Al₂O₃. In the case where the metal oxide film is made of Al₂O₃, the metal oxide film can be easily removed in the step of performing lift-off. Accordingly, it becomes possible to easily manufacture particles to be used in a light-emitting device which emits light of an arbitrary wavelength.

In the step of crushing the lifted-off thin semiconductor film, the thin semiconductor film may be crushed by use of ultrasonic waves. The crushing of the thin semiconductor film by use of ultrasonic waves makes it possible to form particles having sizes approximately equal to the deposition thickness of the thin semiconductor film. Accordingly, it becomes possible to easily manufacture particles to be used in a light-emitting device which emits light of an arbitrary wavelength.

As described previously, a light-emitting device manufacturing method according to the present invention includes the steps of: adding particles of semiconductor crystals to a conductive medium having an energy gap larger than those of the particles; interposing the conductive medium having the particles added thereto in the adding step, between a p-type semiconductor layer and an n-type semiconductor layer; and baking the conductive medium while applying pressure to the conductive medium from both of the p-type and n-type semiconductor layers.

The use of the particles manufactured by an independent process makes it possible to manufacture a light-emitting device which is not restricted by a substrate of the light-emitting device. Accordingly, it becomes possible to manufacture a light-emitting device which emits light of an arbitrary wavelength.

In the step of adding particles, the particles of semiconductor crystals may be added to the conductive polymer liquefied. In the case where the conductive polymer liquefied is used in the step of adding particles, it becomes possible to densely fill spaces between the independently manufactured particles and to easily manufacture a particle layer in which the particles are distributed approximately evenly. Accordingly, it becomes possible to manufacture a light-emitting device which is easily manufactured and which emits light of an arbitrary wavelength.

In the interposing step, the conductive medium may be applied to the surface of the p-type or n-type semiconductor layer by means of spin coating. By applying the conductive medium having the particles added thereto by means of spin coating, the conductive medium can be applied to the surface of the p-type or n-type semiconductor layer so as to have an even thickness. Evenly applying the conductive medium facilitates distributing the particles in the conductive medium approximately evenly. Accordingly, a light-emitting device which emits light of an arbitrary wavelength can be manufactured so as to be homogeneous.

As described above, according to the present invention, it is possible to provide: a light-emitting device which emits light of an arbitrary wavelength; a method of manufacturing particles of semiconductor crystals, which are provided in the light-emitting device; and a method of manufacturing the light-emitting device.

For example, the light-emitting device, the light-emitting device manufacturing method, and the particle manufacturing method according to the present invention can be utilized for lighting, communication, sensors, and light sources mounted on display devices and the like.

Additional advantages and modifications will readily occur to those skilled in the art. Therefore, the invention in its broader aspects is not limited to the specific details and the representative embodiments shown and described herein. Accordingly, various modifications may be made without departing from the scope of the general inventive concept as defined by the appended claims and their equivalents.

What is claimed is:

1. A light-emitting device comprising, in order of mention:
a positive hole supply layer;
a particle layer comprising particles of semiconductor crystals and a conductive medium, the conductive medium which fills spaces between the particles and confines positive holes and electrons in the particles by dint of an energy gap larger than those of the particles; and
an electron supply layer,
wherein positive holes, which are supplied from the positive hole supply layer through the conductive medium to the particles, and electrons, which are supplied from the electron supply layer through the conductive medium to the particles, are caused to recombine to emit light in the particles.

2. A light-emitting device comprising, in order of mention:
a p-type semiconductor layer;
a particle layer comprising particles of semiconductor crystals and a conductive medium, the conductive medium which fills spaces between the particles and confines positive holes and electrons in the particles by dint of an energy gap larger than those of the particles; and
an n-type semiconductor layer,
wherein positive holes, which are supplied from the p-type semiconductor layer through the conductive medium to the particles, and electrons, which are supplied from the n-type semiconductor layer through the conductive medium to the particles, are caused to recombine to emit light in the particles.

3. The light-emitting device according to claim 1, wherein sizes of the particles are not more than the de Broglie wavelengths of an electron and a positive hole.

4. The light-emitting device according to claim 1, wherein the particles have sizes with which a quantum confinement effect manifests.

5. The light-emitting device according to claim 1, wherein sizes of the particles are not less than 0.5 nm nor more than 100 nm.

6. The light-emitting device according to claim 1, wherein the particles have quantum well structures.

7. The light-emitting device according to claim 1, wherein a carrier density of the conductive medium is not less than 10¹⁴ nor more than 10¹⁷ (cm⁻³) .

8. The light-emitting device according to claim 1, wherein the particle layer comprises particles which are different in at least one of size and/or material composition.

9. The light-emitting device according to claim 1, wherein the particle layer comprises a plurality of layers, and the plurality of layers comprise respective particles which are different in at least one of size and/or material composition.

10. The light-emitting device according to claim 8, wherein lights emitted in the particles which are different in at least one of size and/or material composition are mixed into white light by virtue of additive color mixture.

11. The light-emitting device according to claim 1, wherein the particles are made of any one of GaAs/InGaAs, AlAs/InGaAs, and InP/InGaAs.

12. The light-emitting device according to claim 1, wherein the conductive medium is made of a conductive polymer.

13. A method of manufacturing particles, comprising the steps of:
forming any one of a resist film and a metal oxide film on a semiconductor layer;
forming a thin semiconductor film having a thickness approximately equal to sizes of particles to be formed, on any one of the resist film and the metal oxide film;
removing any one of the resist film and the metal oxide film to lift off the thin semiconductor film; and
crushing the lifted-off thin semiconductor film.

14. The method of manufacturing particles according to claim 13, wherein in the step of forming the metal oxide film, AlAs deposited is oxidized in high-temperature water vapor to form Al₂O₃.

15. The method of manufacturing particles according to claim 13, wherein in the step of crushing the lifted-off thin semiconductor film, the thin semiconductor film is crushed by use of ultrasonic waves.

16. A method of manufacturing a light-emitting device, comprising:
adding particles of semiconductor crystals to a conductive medium having an energy gap larger than those of the particles;
interposing the conductive medium having the particles added thereto in the step of adding particles, between a p-type semiconductor and an n-type semiconductor; and
baking the conductive medium interposed in the step of interposing, while applying pressure to the conductive medium from both of the p-type and n-type semiconductors.

17. The method of manufacturing a light-emitting device according to claim 16, wherein in the step of adding particles, the particles of semiconductor crystals are added to the conductive polymer liquefied.

18. The method of manufacturing a light-emitting device according to claim 16, wherein in the step of interposing, the conductive medium is applied to a surface of any one of the p-type and n-type semiconductor layers by means of spin coating.
